(19) United States
(12) Patent Application Publication
(10) Pub. No.: US 2019/0296095 A1
(43) Pub. Date: Sep. 26, 2019

(54) DISPLAY DEVICE INCLUDING A CMOS TRANSISTOR AND METHOD OF MANUFACTURING THE SAME

(71) Applicant: SAMSUNG DISPLAY CO., LTD., YONGIN-SI (KR)

(72) Inventors: Jongchan Lee, Suwon-Si (KR); Taehoon Yang, Yongin-Si (KR); Woonghee Jeong, Seoul (KR); Kyoungwon Lee, Seoul (KR); Yongsu Lee, Seoul (KR)

(21) Appl. No.: 16/437,857

(22) Filed: Jun. 11, 2019

Related U.S. Application Data
(62) Division of application No. 15/871,271, filed on Jan. 15, 2018.

(30) Foreign Application Priority Data
Jun. 16, 2017 (KR) 10-2017-0076861

(51) Int. Cl. H01L 27/32; H01L 27/12

(52) U.S. Cl. CPC H01L 27/3262; H01L 27/124; H01L 27/1262; H01L 2227/323; H01L 27/1288; H01L 27/3248; H01L 27/3276

(57) ABSTRACT

A display device includes at least one transistor. The transistor has an active pattern including a first active area and a second active area. The first active area includes a first channel area and an n-doped area contacting the first channel area. The second active area includes a second channel area and a p-doped area contacting the second channel area. A first insulation layer covers at least a portion of the active pattern. A first gate electrode is disposed on the first insulation layer and at least partially overlaps the first channel area. A second gate electrode is disposed on the first insulation layer and at least partially overlaps the second channel area. A taper angle of the second gate electrode is larger than a taper angle of the first gate electrode.

### CROSS-REFERENCE TO RELATED APPLICATION

This application is a Division of co-pending U.S. patent application Ser. No. 15/871,271, filed on Jan. 15, 2018, which claims priority to and the benefit of Korean Patent Application No. 10-2017-0076861, filed on Jun. 16, 2017 in the Korean Intellectual Property Office, the entire disclosures of which are incorporated by reference herein in their entirety.

### TECHNICAL FIELD

The present disclosure relates to a display device and, more particularly, to a display device including a CMOS (complementary metal oxide silicon) transistor and a method for manufacturing the display device.

### DISCUSSION OF THE RELATED ART

A substrate including a thin film transistor is used for driving pixels of a display device such as a liquid crystal display device, an organic light-emitting display device, or the like.

A channel of the thin film transistor may include amorphous silicon, polycrystalline silicon (polysilicon), oxide semiconductor, or the like. In an organic light-emitting display device, polysilicon having a relatively high carrier mobility is widely used for a channel material, and polysilicon may also be used for forming a PMOS transistor or an NMOS transistor, according to carrier charge or dopant.

To achieve display devices with high resolution, wiring may be more tightly integrated and thin film transistors may be reduced in size.

### SUMMARY

A display device includes at least one transistor. The transistor has an active pattern including a first active area and a second active area. The first active area includes a first channel area and an n-doped area contacting the first channel area. The first active area is doped with n-type impurities. The second active area includes a second channel area and a p-doped area contacting the second channel area. The second active area is doped with p-type impurities. A first insulation layer covers at least a portion of the active pattern. A first gate electrode is disposed on the first insulation layer and at least partially overlaps the first channel area. A second gate electrode is disposed on the first insulation layer and at least partially overlaps the second channel area. A taper angle of the second gate electrode is larger than a taper angle of the first gate electrode.

A method for manufacturing a display device includes forming a semiconductor pattern including a first semiconductor area and a second semiconductor area on a base substrate. A first insulation layer is formed to cover the semiconductor pattern. A gate metal layer is formed on the first insulation layer. The gate metal layer is etched to form a gate pattern at least partially overlapping the first semiconductor area. A first area of the first semiconductor area is doped with a high concentration of n-type impurities to form a high-concentration-doped area. The gate pattern is etched to form a first gate electrode having a taper angle smaller than a taper angle of the gate pattern. A second area of the first semiconductor area, contacting the first area of the first semiconductor area, is doped with a low concentration of n-type impurities to form a low-concentration-doped area. The gate metal layer is etched to form a second gate electrode at least partially overlapping the second semiconductor area and having a taper angel larger than the taper angle of the first gate electrode. The second semiconductor area is doped with p-type impurities to form a p-doped area.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a circuit diagram illustrating a pixel of a display device according to an exemplary embodiment of the present disclosure;

FIGS. 2 to 13 are cross-sectional views illustrating a method for manufacturing a display device according to an exemplary embodiment of the present disclosure; and

FIGS. 14 to 21 are cross-sectional views illustrating a method for manufacturing a display device according to an exemplary embodiment of the present disclosure.

### DETAILED DESCRIPTION

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

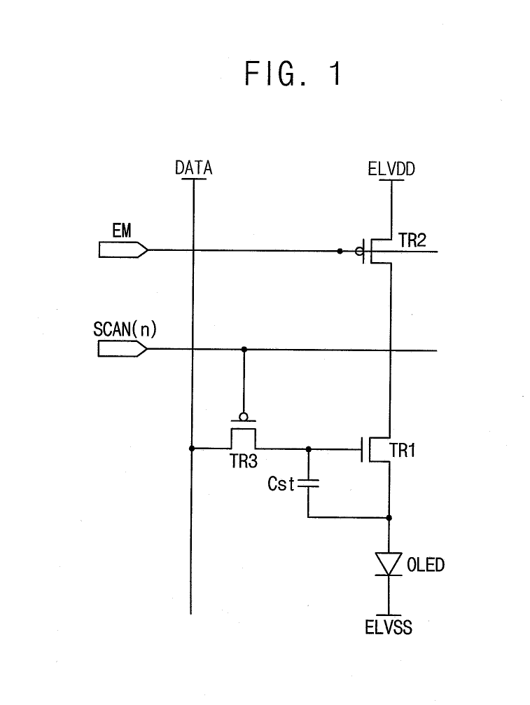

FIG. 1 is a circuit diagram illustrating a pixel of a display device according to an exemplary embodiment of the present disclosure. The display device, according to an exemplary embodiment of the present disclosure, may be an organic light-emitting display device. The organic light-emitting display device may include an array of pixels.

Referring to FIG. 1, a pixel PX of the display device may include an organic light-emitting diode OLED, a first transistor TR1, a second transistor TR2, a third transistor TR3, and a storage capacitor Cst.

The organic light-emitting diode OLED may emit light based on a driving current. The organic light-emitting diode OLED may include a first terminal and a second terminal. In an exemplary embodiment of the present disclosure, the first terminal of the organic light-emitting diode OLED may receive a first power voltage ELVDD, and the second terminal of the organic light-emitting diode OLED may receives a second power voltage ELVSS. In an exemplary embodiment of the present disclosure, the first terminal may be an anode, and the second terminal may be a cathode.

The first transistor TR1 may include a gate terminal, a first terminal, and a second terminal. The first terminal of the first transistor TR1 may be connected to the second transistor TR2, and the second terminal of the first transistor TR1 may be connected to the organic light-emitting diode OLED. The gate terminal of the first transistor TR1 may be connected to the third transistor TR3.

The first transistor TR1 may generate the driving current based on the first power voltage ELVDD applied thereto. In an exemplary embodiment of the present disclosure, a desired gray scale value may be implemented based on an amount of the driving current provided to the organic light-emitting diode OLED. According to an exemplary embodiment of the present disclosure, a desired gray scale value may be implemented using a fixed level of driving current based on a total length of time during which the driving current is provided to the organic light-emitting diode OLED within one frame.

The second transistor TR2 may include a gate terminal, a first terminal, and a second terminal. The gate terminal may receive an emission signal EM. The first terminal may receive the first power voltage ELVDD. The second terminal may be connected to the first terminal of the first transistor TR1.

The second transistor TR2 may provide the first power voltage ELVDD to the first terminal of the first transistor TR1 during an active period of the emission signal EM. Furthermore, the second transistor TR2 may discontinue the first power voltage ELVDD during an inactive period of the emission signal EM. When the first power voltage ELVDD is provided to the first terminal of the first transistor TR1 during the active period of the emission signal EM, the first transistor TR1 may generate the driving current.

The third transistor TR3 may include a gate terminal, a first terminal and a second terminal. The gate terminal may receive a scan signal Scan[n] from a scan line (or a gate line). The first terminal may be connected to a data line to receive a data signal DATA. The second terminal may be connected to the gate terminal of the first transistor TR1.

The third transistor TR3 may provide the data signal DATA to the gate terminal of the first transistor TR1 during an active period of the scan signal Scan[n] of a current stage.

The storage capacitor Cst may be connected to and between the second terminal of the third transistor TR3 and the first terminal of the organic light-emitting diode OLED. Thus, the driving current generated by the first transistor TR1 may be provided to the organic light-emitting diode OLED based on a voltage level maintained by the storage capacitor Cst.

In an exemplary embodiment of the present disclosure, the first transistor TR1 may be an NMOS transistor. The second transistor TR2 and the third transistor TR3 may be PMOS transistors.

Hereinafter, a method for manufacturing the organic light-emitting display device will be described with reference to the accompanying drawings. Cross-sections of the first transistor TR1 and the second transistor TR2 may be shown in the accompanying drawings. The third transistor TR3 may be manufactured by a same method as that of the second transistor TR2.

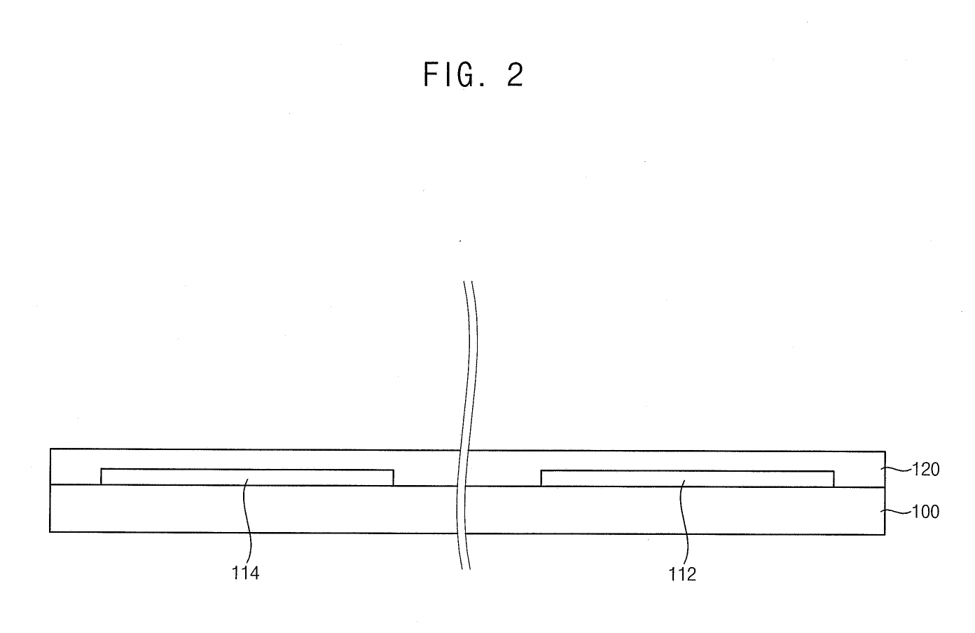

FIGS. 2 to 13 are cross-sectional views illustrating a method for manufacturing a display device according to an exemplary embodiment of the present disclosure.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of exemplary embodiments.

Referring to FIG. 2, a semiconductor pattern is formed on a base substrate 100.

For example, the base substrate 100 may include an insulating material such as glass, quartz, polymer or the like. The polymer may include polyethylene terephthalate, polyethylene naphthalate, polytether ketone, polycarbonate, polyarylate, polyether sulfone, polyimide or the like.

The semiconductor pattern may include a first semiconductor area 112 and a second semiconductor area 114. In an exemplary embodiment of the present disclosure, the first semiconductor area 112 may be spaced apart from the second semiconductor are 114. In an exemplary embodiment of the present disclosure, the first semiconductor area 112 may be disposed in contact with the second semiconductor are 114.

The semiconductor pattern may include polysilicon. In order to form the semiconductor pattern, an amorphous silicon layer may be formed on the base substrate 100 and then crystallized to form a polysilicon layer.

For example, the amorphous silicon layer may be formed by sputtering, low-pressure chemical vapor deposition (LPCVD), plasma-enhanced chemical vapor deposition (PECVD) or the like. The amorphous silicon layer may be crystallized through excimer laser annealing (ELA), sequential lateral solidification (SLS) or the like.

For example, the polysilicon layer may be polished by chemical mechanical polishing (CMP) or the like to planarize a surface thereof. Thereafter, the polysilicon layer may be patterned by a photolithography or the like to form the semiconductor pattern. The semiconductor pattern may be doped with n-type impurities or p-type impurities, as desired.

A first insulation layer 120 may be disposed over the semiconductor pattern so as to fully cover the semiconductor pattern. The first insulation layer 120 may insulate a channel of the semiconductor pattern from a gate electrode formed on the first insulation layer 120.

For example, the first insulation layer 120 may include silicon oxide, silicon nitride, silicon carbide or a combination thereof. Furthermore, the first insulation layer 120 may include an insulating metal oxide such as aluminum oxide, tantalum oxide, hafnium oxide, zirconium oxide, titanium oxide or the like. For example, the first insulation layer 120 may have a single-layered structure or a multiple-layered structure including silicon nitride and/or silicon oxide.

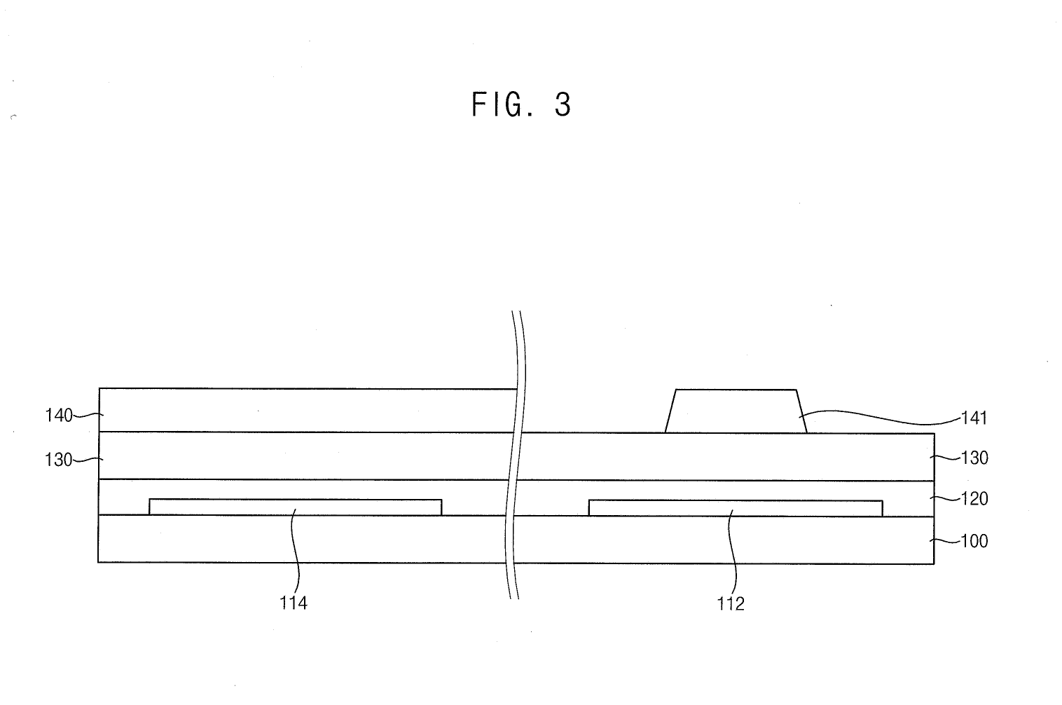

Referring to FIG. 3, a gate metal layer 130 is formed on the first insulation layer 120, and a first photoresist layer 140 is formed on the gate metal layer 130.

For example, the gate metal layer 130 may include gold (Au), silver (Ag), aluminum (Al), copper (Cu), nickel (Ni), platinum (Pt), magnesium (Mg), chromium (Cr), tungsten (W), molybdenum (Mo), titanium (Ti), tantalum (Ta), and/or an alloy thereof, and may have a single-layered structure or a multiple-layered structure including different metal layers. In an exemplary embodiment of the present disclosure, the gate metal layer 130 may be relatively thick, for example, the metal layer 130 may be greater than or equal to 1 μm to achieve high resolution. However, exemplary embodiments are not limited thereto, and the gate metal layer 130 may have a thickness that is less than 1 μm.

The first photoresist layer 140 is patterned to at least partially expose the gate metal layer 130. For example, the first photoresist layer 140 may include a first mask pattern 141 at least partially overlapping the first semiconductor area 112.

For example, a photoresist composition including a binder resin such as a phenol resin, an acryl resin or the like may be coated, exposed to a light, and developed to form the first photoresist layer 140.

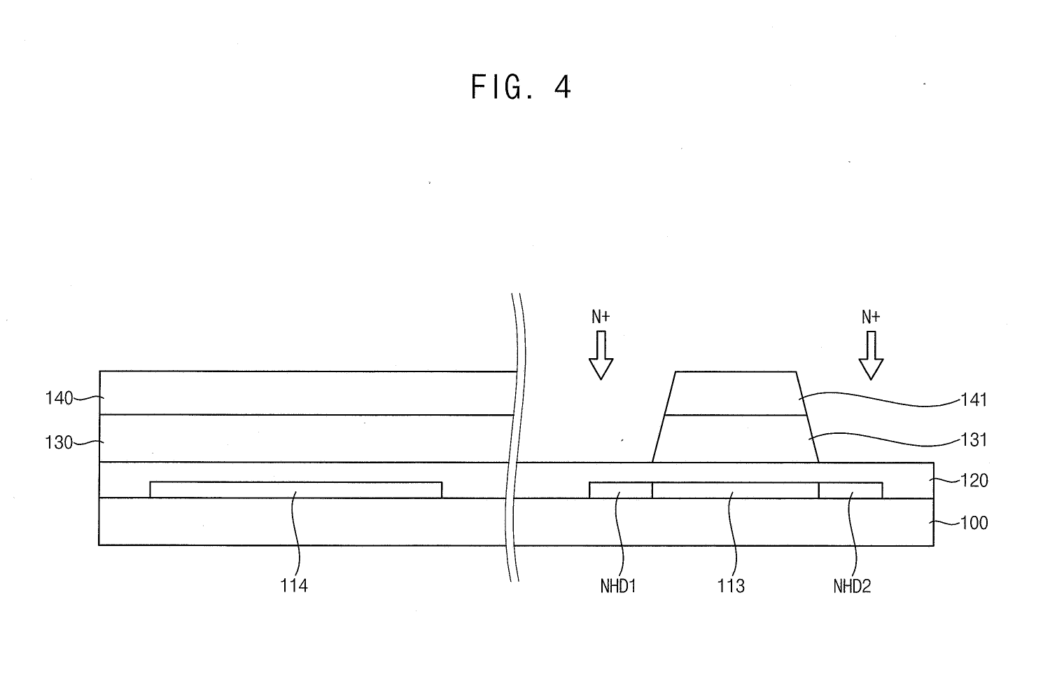

Referring to FIG. 4, the gate metal layer 130 is etched using the first mask pattern 141 to form a gate pattern 131. For example, the gate metal layer 130 may be etched by a dry-etching process using plasma or the like.

As the gate pattern 131 is formed, the first insulation layer 120 may be partially exposed in an area surrounding or adjacent to the gate pattern 131. Furthermore, the first insulation layer 120 may be partially etched by the dry-etching process to reduce its thickness.

Thereafter, a high concentration of n-type impurities such as phosphor, arsenic or the like may be provided to the first semiconductor area 112 through an exposed portion of the first insulation layer 120. Thus, a peripheral portion of the first semiconductor area 112, which does not overlap the gate pattern 131, is doped with a high concentration of n-type impurities to form a first high-concentration-doped area NHD1 and a second high-concentration-doped area NHD2. In the first semiconductor area 112, an overlapping portion 113, which overlaps the gate pattern 131, is protected by the gate pattern 131 to remain undoped.

The second semiconductor area 114 is protected by the gate metal layer 130 and the first photoresist layer 140, which are disposed on the second semiconductor area 114. Thus, the second semiconductor area 114 remains undoped.

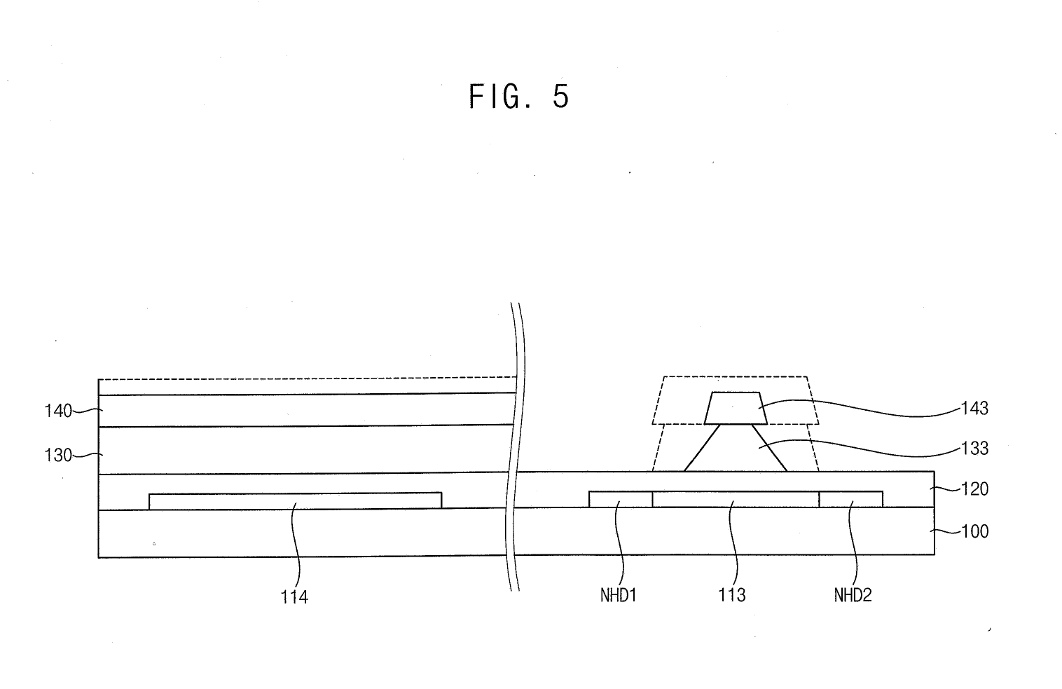

Referring to FIG. 5, the gate pattern 131 and the first mask pattern 141 are etched by an ashing process. As a result of the ashing process, a width of the gate pattern 131 is reduced to form a first gate electrode 133. The ashing process may etch a side surface of the gate pattern 131 to form a skew. Thus, the first gate electrode 133 may have a taper angle smaller than that of the gate pattern 131. Hereinafter, “taper angle” may be defined by an angle between a lower surface and a side surface of a metal pattern.

As a result of the ashing process, a width of the gate pattern 131 is reduced so that the first insulation layer 120 is exposed in an area surrounding or adjacent to the first gate electrode 133.

For example, the ashing process may be performed using plasma. The ashing process may etch a metal, an inorganic insulating material, and an organic insulating material like a dry-etching process. Thus, the gate pattern 131, the first photoresist layer 140 including the first mask pattern 141, and the first insulation layer 120 may be partially etched by the ashing process.

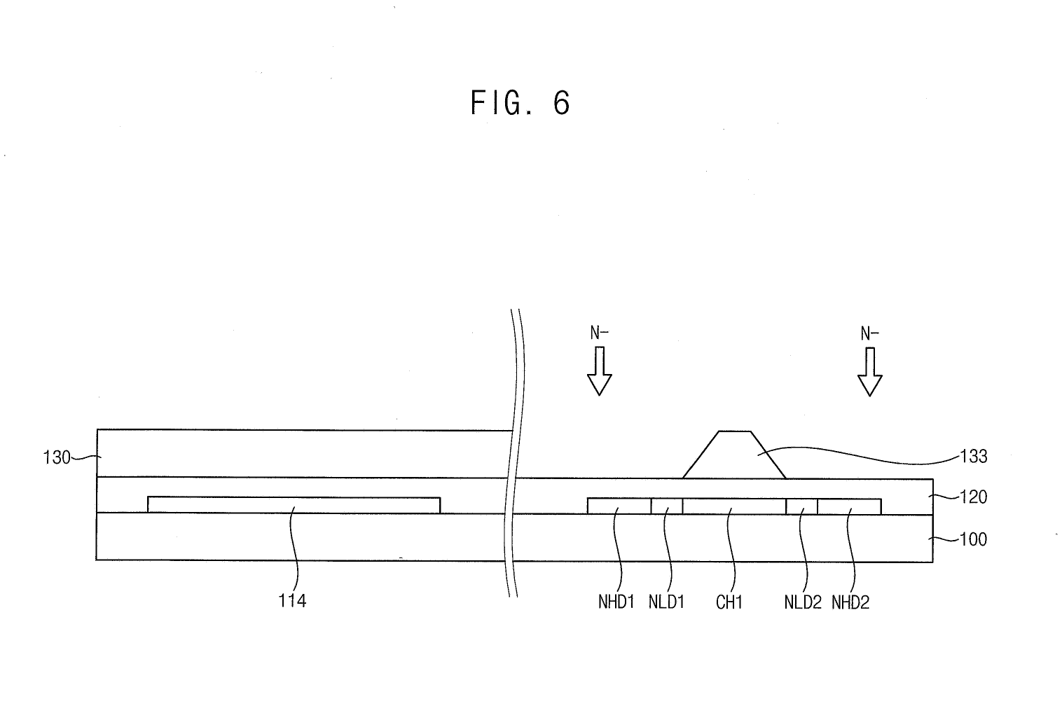

Referring to FIG. 6, a low concentration of n-type impurities such as phosphor, arsenic or the like may be applied to a remaining semiconductor pattern 113 through an exposed portion of the first insulation layer 120. Thus, a peripheral portion of the remaining semiconductor pattern 113, which does not overlap the first gate electrode 133, is doped with a low concentration of n-type impurities to form a first low-concentration-doped area NLD1 and a second low-concentration-doped area NLD2. In the remaining semiconductor pattern 113, a portion overlapping the first gate electrode 133 is protected by the first gate electrode 133. Thus, the portion remains without being doped to define a first channel area CH1.

The process for providing n-type impurities with a low concentration may be performed after or before the first photoresist layer 140 and a remaining mask pattern 143 are removed.

A length of the first low-concentration-doped area NLD1 and the second low-concentration-doped area NLD2 may vary depending on a manufacturing process and a desired device characteristic. For example, the length of the first low-concentration-doped area NLD1 and the second low-concentration-doped area NLD2 may be about 0.2 μm to about 2 μm.

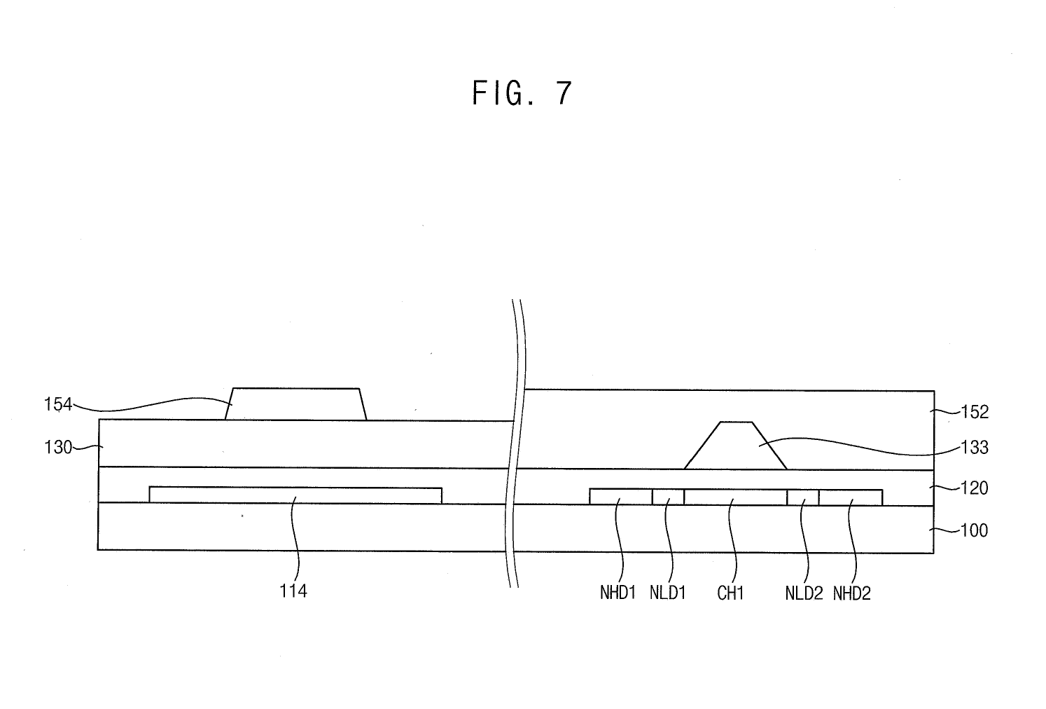

Referring to FIG. 7, a second photoresist layer 152 is formed to cover the first gate electrode 133, the first insulation layer 120, and the gate metal layer 130. The second photoresist layer 152 may be patterned to partially expose the gate metal layer 130. For example, the second photoresist layer 152 may include a second mask pattern 154 at least partially overlapping the second semiconductor area 114.

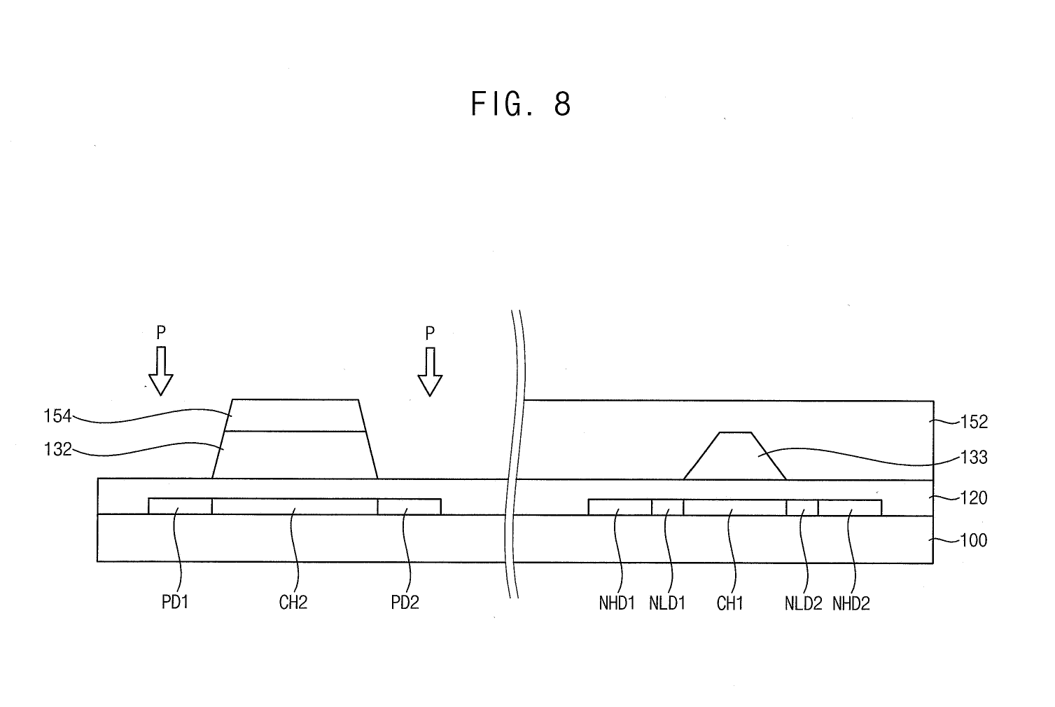

Referring to FIG. 8, the gate metal layer 130 is etched using the second mask pattern 154 as mask to form a second gate electrode 132. For example, the gate metal layer 130 may be etched by a dry-etching process using plasma or the like.

The first insulation layer 120 may be exposed in an area surrounding or adjacent to the second gate electrode 132. Furthermore, the first insulation layer 120 may be partially etched by the dry-etching process to have a reduced thickness.

Thereafter, p-type impurities such as boron or the like may be provided to the second semiconductor area 114 through an exposed portion of the first insulation layer 120. As a result, a peripheral portion of the second semiconductor area 114, which does not overlap the second gate electrode 132, is doped with p-type impurities to form a first p-doped area PD1 and a second p-doped area PD2. In the second semiconductor area 114, a portion overlapping the second gate electrode 132 is protected by the second gate electrode 132. Thus, the portion remains without being doped to define a second channel area CH2.

In an exemplary embodiment of the present invention, the gate metal layer 130 may be used for forming other electrodes and wirings such as a gate electrode of the third transistor TR3, the gate line, an emission signal line or the like as well as the first gate electrode 133 and the second gate electrode 132. According to exemplary embodiments of the present disclosure, other members except for the first gate electrode 133 may be formed with the second gate electrode 132. Thus, the first photoresist layer 142 may cover the entire gate metal layer 130 except for an area required for forming the first transistor TR1, for example, an area overlapping the first semiconductor area 112.

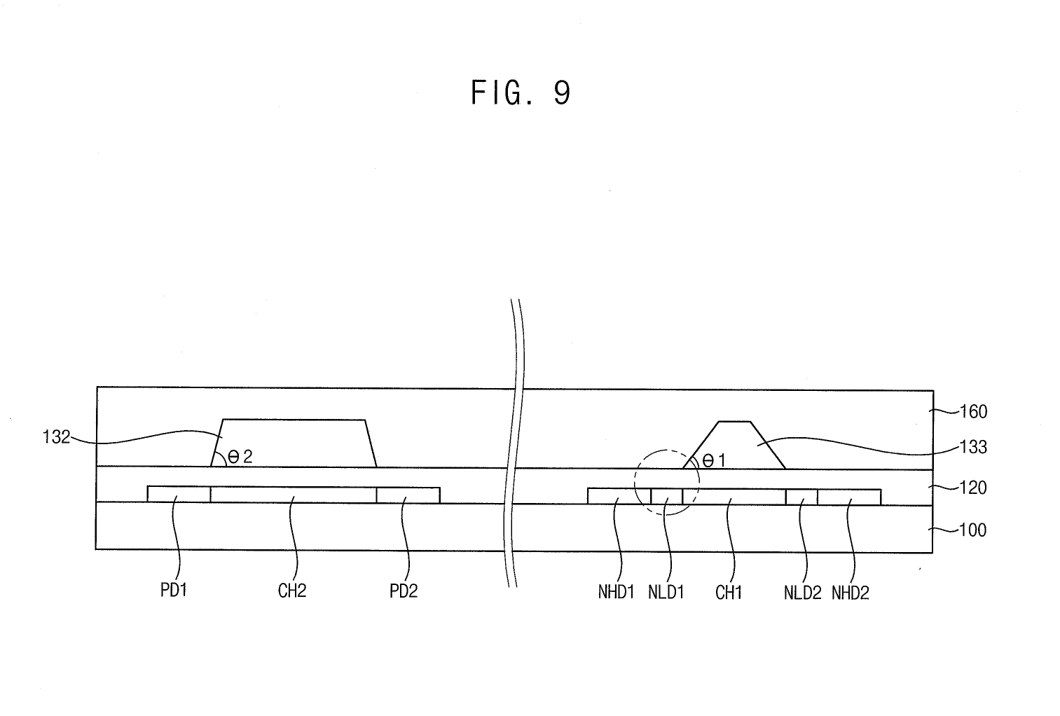

Referring to FIG. 9, the second photoresist layer 152 is removed, and a second insulation layer 160 is formed to cover the first gate electrode 133, the second gate electrode 132 and an exposed portion of the first insulation layer 120.

For example, the second insulation layer 160 may include silicon oxide, silicon nitride, silicon carbide or a combination thereof. Furthermore, the second insulation layer 160 may include an insulating metal oxide such as aluminum oxide, tantalum oxide, hafnium oxide, zirconium oxide, titanium oxide or the like. For example, the second insulation layer 160 may have a single-layered structure or a multiple-layered structure including silicon nitride and/or silicon oxide. When the second insulation layer 160 includes an organic insulating material or further includes an organic insulation layer, the second insulation layer 160 may include polyimide, polyamide, acryl resin, phenol resin, benzocyclobutene (BCB) or the like.

The first gate electrode 133 and a first active area including the first channel area CH1, the first low-concentration-doped area NLD1, the second low-concentration-doped area NLD2, the first high-concentration-doped area NHD1, and the second high-concentration-doped area NHD2 may form an NMOS transistor. For example, the first low-concentration-doped area NLD1 and the first high-concentration-doped area NHD1 may define a source area. The second low-concentration-doped area NLD2 and the second high-concentration-doped area NHD2 may define a drain area. The first low-concentration-doped area NLD1, the second low-concentration-doped area NLD2, the first high-concentration-doped area NHD1, and the second high-concentration-doped area NHD2 may be referred as an n-doped area.

The second gate electrode 132 and a second active area including the second channel area CH2, the first p-doped area PD1 and the second p-doped area PD2 may form a PMOS transistor. For example, the first p-doped area PD1 may define a source area, and the second p-doped area PD2 may define a drain area. The polysilicon pattern including the first active area and the second active area may be referred as an active pattern.

As described above, the first gate electrode 133 is formed through a dry-etching process and an ashing process, and the second gate electrode 132 is formed through a dry-etching process. Thus, a taper angle θ1 of the first gate electrode 133 may be smaller than a taper angle θ2 of the second gate electrode 132. The taper angle θ1 of the first gate electrode 133 may be determined according to an ashing time and an initial taper angle that exists before the ashing process. For example, as the ashing time increases, the taper angle θ1 of the first gate electrode 133 may decrease.

For example, the taper angle θ1 of the first gate electrode 133 may be about 20° to about 80°. The taper angle θ2 of the second gate electrode 132 may be about 30° to about 90°. When the taper angle θ2 of the second gate electrode 132 is larger than 90°, thereby forming an inversely-tapered shape, an upper layer formed on the second gate electrode 132 may have defects due to step difference. When the taper angle θ2 of the second gate electrode 132 is smaller than 30°, a hump may appear, or a resistance of the second gate electrode 132 may increase.

According to an exemplary embodiment of the present invention, the taper angle θ1 of the first gate electrode 133 may be about 30° to about 70°, and the taper angle θ2 of the second gate electrode 132 may be about 60° to about 90°.

According to an exemplary embodiment of the present invention, a difference between the taper angle θ1 of the first gate electrode 133 and the taper angle θ2 of the second gate electrode 132 may be about 20° to about 40°. When the difference between the taper angle θ1 of the first gate electrode 133 and the taper angle θ2 of the second gate electrode 132 is smaller than 20°, a length of the low-concentration-doped areas in the NMOS transistor may be reduced. Thus, leakage current and off-current may increase. Furthermore, when the difference between the taper angle θ1 of the first gate electrode 133 and the taper angle θ2 of the second gate electrode 132 is larger than 40°, a thickness of an area exposed to both the dry-etching process and the ashing process, for example, such as the high-concentration-doped area, may be excessively decreased thereby deteriorating device characteristics. The difference between the taper angle θ1 of the first gate electrode 133 and the taper angle θ2 of the second gate electrode 132 may accordingly be about 30° to about 40°, for example, may be about 35° to about 40°.

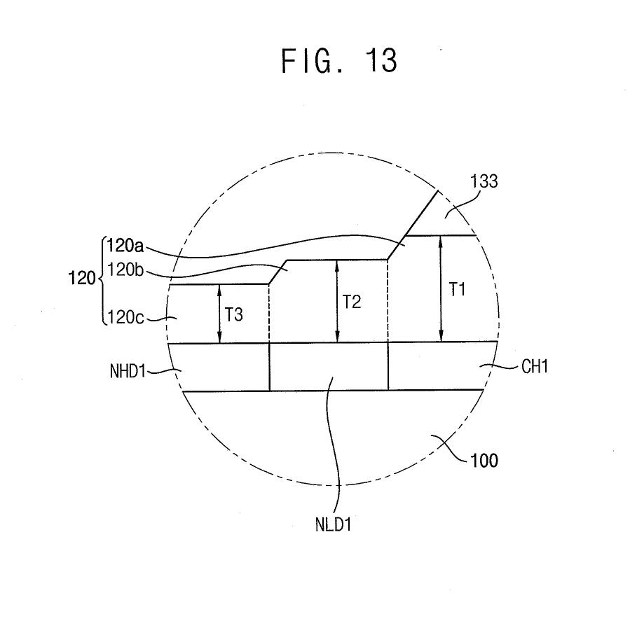

Referring to FIG. 13, an enlarged cross-sectional view illustrates the first insulation layer of a display device according to an exemplary embodiment of the present disclosure. Referring to FIG. 13, the first insulation layer 120 may include a first area 120a, which is disposed between the first gate electrode 133 and the first channel area CH1, a second area 120b overlapping and corresponding to the first low-concentration-doped area NLD1, and a third area 120c overlapping and corresponding to the first high-concentration-doped area NHD1.

The first area 120a is protected by the first gate electrode 133 to remain as a non-etched area. The second area 120b is etched in the ashing process for forming the first gate electrode 133. The third area 120c is etched in the ashing process and in the dry-etching process for forming the gate pattern 131. Thus, the thickness of the second area 120b is smaller than the thickness of the first area 120a, and the thickness of the third area 120c is smaller than the thickness of the second area 120b. For example, the thickness of the third area 120c may be equal to or more than 80% of the thickness of the first area 120a. When the thickness of the third area 120c is excessively small, transistor characteristics may be deteriorated. For example, the thickness of the third area 120c may be 80% to 90% of the thickness of the first area 120a.

In FIG. 13, the first area 120a, the second area 120b and the third area 120c may be shown to have step difference therebetween. However, the thickness of the first insulation layer 120 may be gradually reduced in each of the areas.

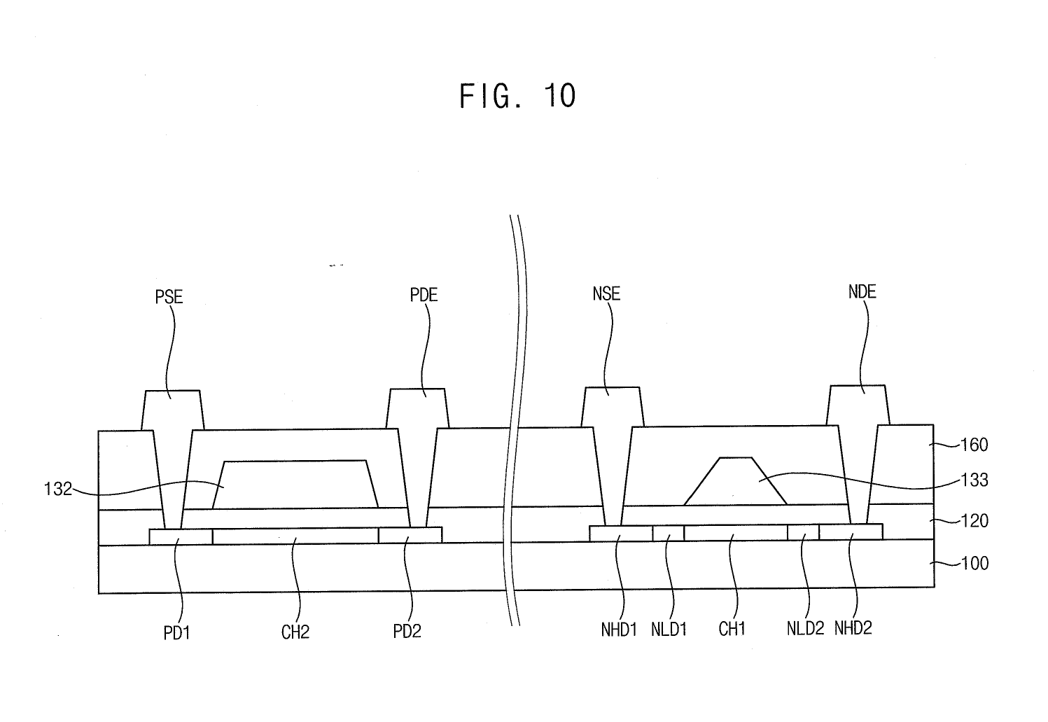

Referring to FIG. 10, the first insulation layer 120 and the second insulation layer 160 are patterned to form through-holes exposing the first high-concentration-doped area NHD1, the second high-concentration-doped area NHD2, the first p-doped area PD1, and the second p-doped area PD2. Thereafter, a data metal layer is formed on the second insulation layer 160, and patterned to form a data metal pattern including a first source electrode NSE, a first drain electrode NDE, a second source electrode PSE, and a second drain electrode PDE.

For example, the data metal layer may include gold (Au), silver (Ag), aluminum (Al), copper (Cu), nickel (Ni), platinum (Pt), magnesium (Mg), chromium (Cr), tungsten (W), molybdenum (Mo), titanium (Ti), tantalum (Ta) or an alloy thereof, and may have a single-layered structure or a multiple-layered structure including different metal layers.

The first source electrode NSE may be connected to the first high-concentration-doped area NHD1. The first drain electrode NDE may be connected to the second high-concentration-doped area NHD2. The second source electrode PSE may be connected to the first p-doped area PD1. The second drain electrode PDE may be connected to the second p-doped area PD2.

In an exemplary embodiment of the present disclosure, the drain area of the p-doped area may be electrically connected to the source area of the n-doped area. However, exemplary embodiments of the present inventive concept are not limited thereto, and the above configuration may be variously changed depending on combination of an NMOS transistor and a PMOS transistor. For example, a drain area of the third transistor TR3 may be electrically connected to the first gate electrode 133.

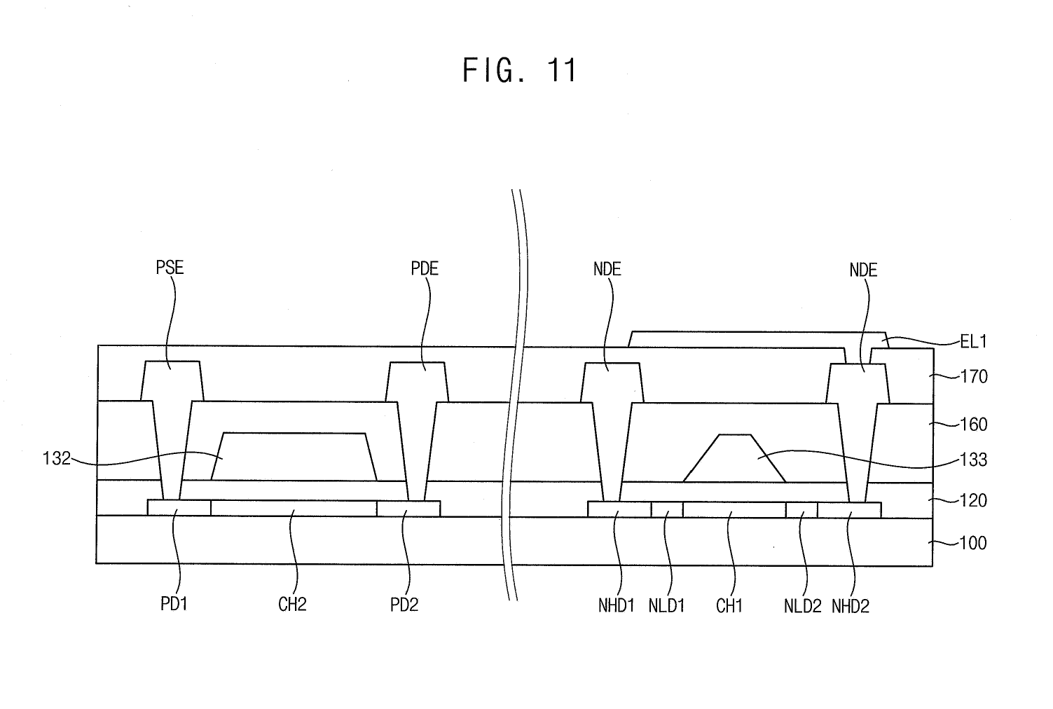

Referring to FIG. 11, a third insulation layer 170 is formed on the data metal pattern, and the third insulation layer 170 is patterned to expose the first drain electrode NDE. A first electrode metal layer is formed on the third insulation layer 170, and the first metal layer is patterned to form a first electrode EL1 contacting the first drain electrode NDE.

For example, the third insulation layer 170 may include an inorganic insulating material, an organic insulating material or a combination thereof, which are previously described.

The first electrode EL1 may be a pixel electrode of the display device. The first electrode EL1 may be formed as a transmitting electrode or as a reflecting electrode, depending on an emission type of the display device. When the first electrode EL1 is a transmitting electrode, the first electrode EL1 may include indium tin oxide, indium zinc oxide, zinc tin oxide, indium oxide, zinc oxide, tin oxide or the like. When the first electrode EL1 is a reflecting electrode, the first electrode EL1 may include gold (Au), silver (Ag), aluminum (Al), copper (Cu), nickel (Ni), platinum (Pt), magnesium (Mg), chromium (Cr), tungsten (W), molybdenum (Mo), titanium (Ti) or a combination thereof, and may have a stacked structure further including one or more of the material that may be used for the transmitting electrode.

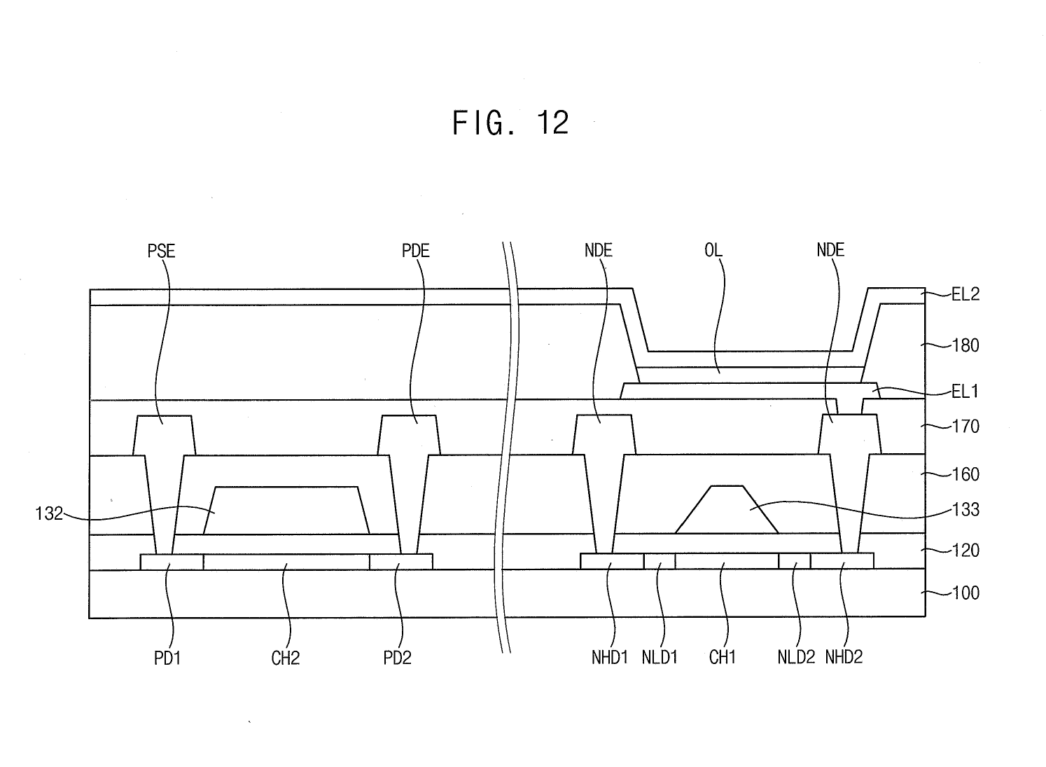

Referring to FIG. 12, a pixel-defining layer 180 is formed on the first electrode EL1 and the third insulation layer 170. The pixel-defining layer 180 includes an opening that exposes at least a portion of the first electrode EL1. For example, the pixel-defining layer 180 may include an organic insulating material.

A light-emitting layer OL may be formed on the first electrode EL1. The light-emitting layer OL may include at least one functional layer such as a hole-injection layer, a hole-transporting layer, an organic light-emitting layer, an electron-transporting layer, an electron-injecting layer or the like, and may have a single-layered structure and a multiple-layered structure.

The light-emitting layer OL may include a low molecular weight organic compound or a high molecular weight organic compound. Examples of the low molecular weight organic compound may include copper phthalocyanine, N,N′-diphenylbenzidine, (tris-(8-hydroxyquinoline)aluminum or the like. Examples of the high molecular weight organic compound may include poly(3,4-ethylenedioxythiophene), polyaniline, poly-phenylenevinylene, polyfluorene or the like.

In an exemplary embodiment of the present disclosure, the light-emitting layer OL may emit a red light, a green light or a blue light. In an exemplary embodiment of the present disclosure, the light-emitting layer OL may emit a white light. The light-emitting layer OL emitting a white light may have a multiple-layered structure including a red-emitting layer, a green-emitting layer, and a blue-emitting layer, or a single-layered structure including a mixture of a red-emitting material, a green-emitting material, and a blue-emitting material.

For example, the light-emitting layer OL may be formed through a screen printing process, an ink-jet printing process or the like.

A second electrode EL2 may be formed on the light-emitting layer OL. The second electrode EL2 may be formed as a transmitting electrode or a reflecting electrode depending on an emission type of the display device. For example, when the second electrode EL2 is a transmitting electrode, the second electrode EL2 may include lithium (Li), calcium (Ca), lithium fluoride (LiF), aluminum (Al), magnesium (Mg), or a combination thereof, and the display device may further include a sub electrode or a bus electrode line, which includes indium tin oxide, indium zinc oxide, zinc tin oxide, indium oxide, zinc oxide, tin oxide, or the like.

In an exemplary embodiment of the present disclosure, the organic light-emitting display device may have a front-emission type, in which a light exits through the second electrode EL2. In an exemplary embodiment of the present disclosure, the organic light-emitting display device may have a rear-emission type in which a light exits in an opposing direction.

According to an exemplary embodiment of the present disclosure, a PMOS transistor is formed after an NMOS transistor is formed. Thus, because the second photoresist layer for protecting a early-formed transistor is exposed to one dry-etching process, damage to a transistor or a wiring may be reduced and/or prevented. However, the present inventive concept is not limited thereto, and an NMOS transistor may be formed after a PMOS transistor is formed in an exemplary embodiment of the present disclosure.

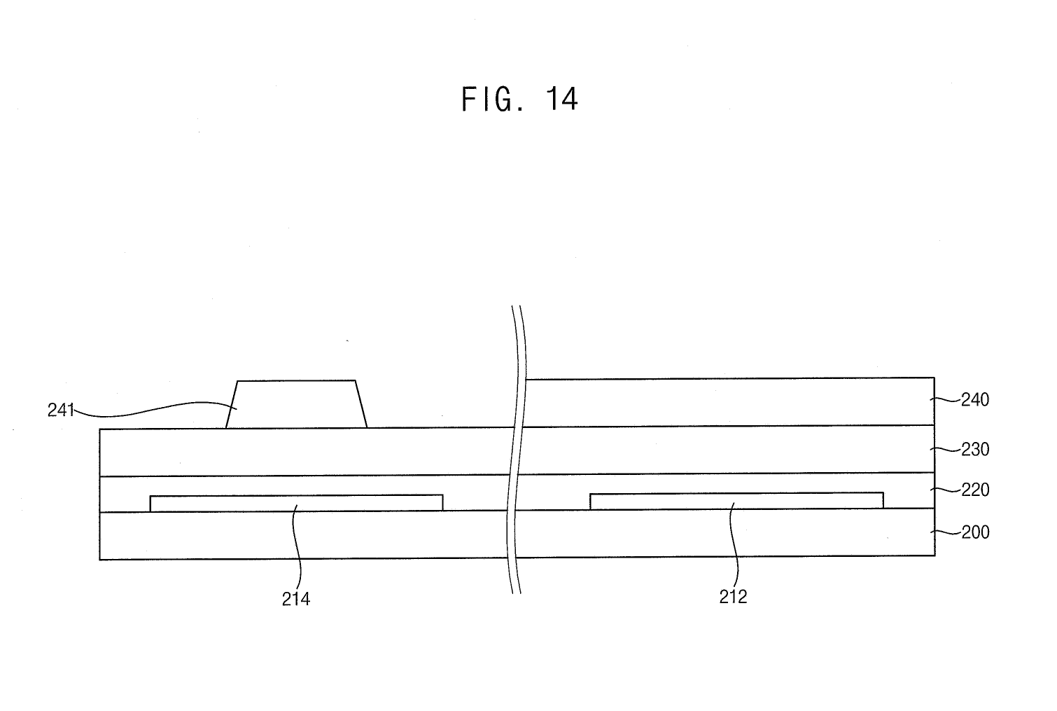

FIGS. 14 to 21 are cross-sectional views illustrating a method for manufacturing a display device according to an exemplary embodiment of the present disclosure. The method may be substantially same as the method previously explained with reference to FIGS. 2 to 13 except that an NMOS transistor is formed after a PMOS transistor is formed. Thus, any omitted explanation may be assumed to be substantially the same as the description of corresponding elements provided above.

Referring to FIG. 14, a semiconductor pattern is formed on a base substrate 200.

The semiconductor pattern may include a first semiconductor area 212 and a second semiconductor area 214. The semiconductor pattern may include a polycrystalline silicon (polysilicon).

A first insulation layer 220 is formed to cover the semiconductor pattern. A gate metal layer 230 is formed on the first insulation layer 220, and a first photoresist layer 240 is formed on the gate metal layer 230.

The first photoresist layer 240 is patterned to partially expose the gate metal layer 230. For example, the first photoresist layer 240 may include a first mask pattern 231 at least partially overlapping the second semiconductor area 214.

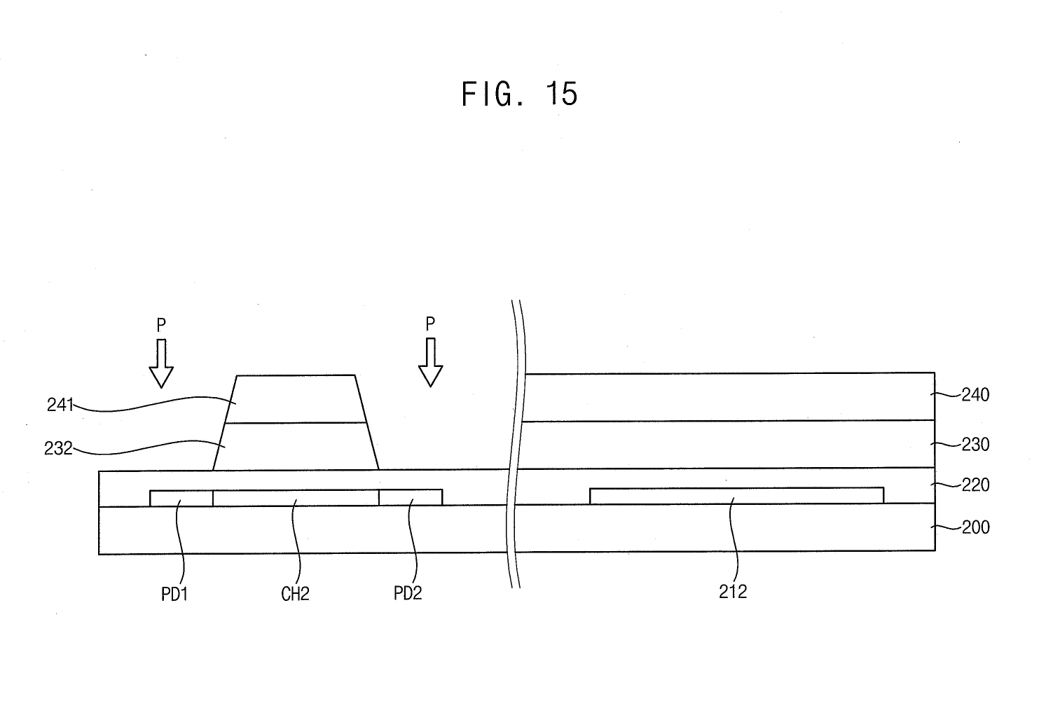

Referring to FIG. 15, the gate metal layer 230 is etched using the first mask pattern 241 as a mask to form a second gate electrode 232. For example, the gate metal layer 230 may be etched by a dry-etching process using plasma or the like.

As the second gate electrode 232 is formed, the first insulation layer 220 may be formed in an area surrounding or adjacent to the second gate electrode 232.

Thereafter, p-type impurities such as boron or the like may be provided to the second semiconductor area 214 through an exposed portion of the first insulation layer 220. As a result, a peripheral portion of the second semiconductor area 214, which does not overlap the second gate electrode 232, is doped with p-type impurities to form a first p-doped area PD1 and a second p-doped area PD2. In the second semiconductor area 214, a portion overlapping the second gate electrode 232 is protected by the second gate electrode 132. Thus, the remaining un-doped portion of the second semiconductor area 214 may define a second channel area CH2.

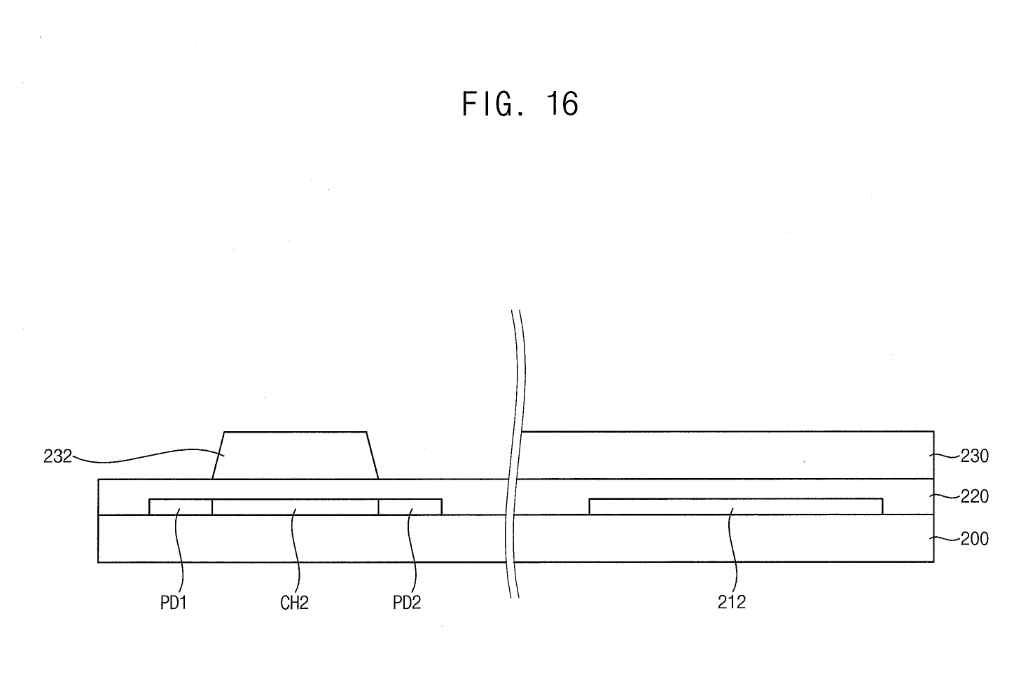

Referring to FIG. 16, the first insulation layer 240 including the first mask pattern 241 is removed.

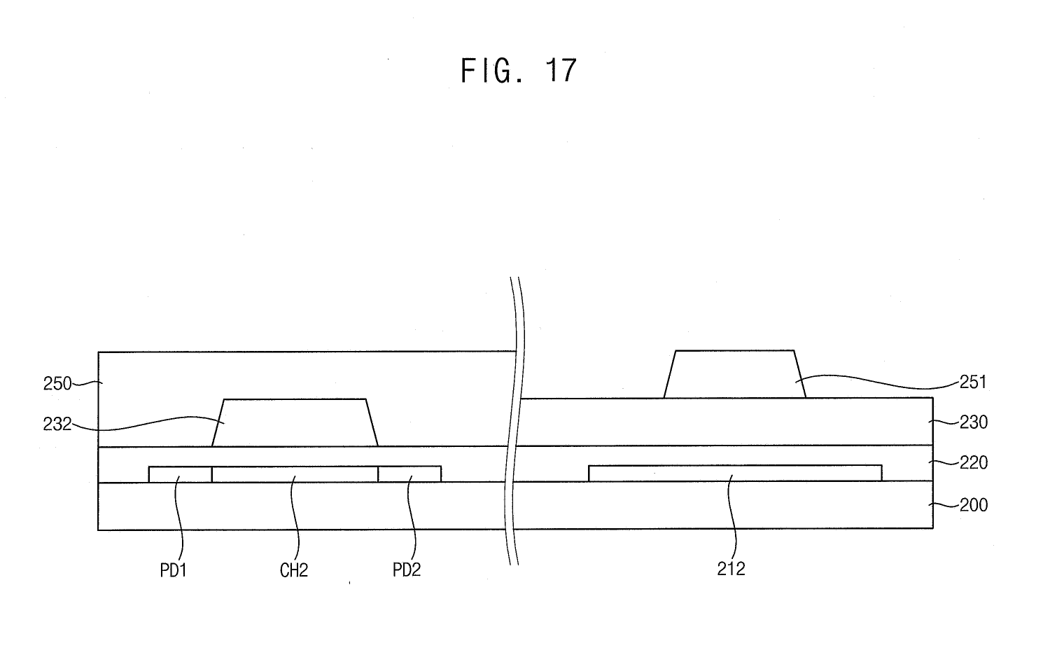

Referring to FIG. 17, a second photoresist layer 250 is formed to cover the second gate electrode 232, the first insulation layer 220, and the gate metal layer 230. The second photoresist layer 250 is patterned to partially expose the gate metal layer 230. For example, the second photoresist layer 250 may include a second mask pattern 251 at least partially overlapping the first semiconductor area 212.

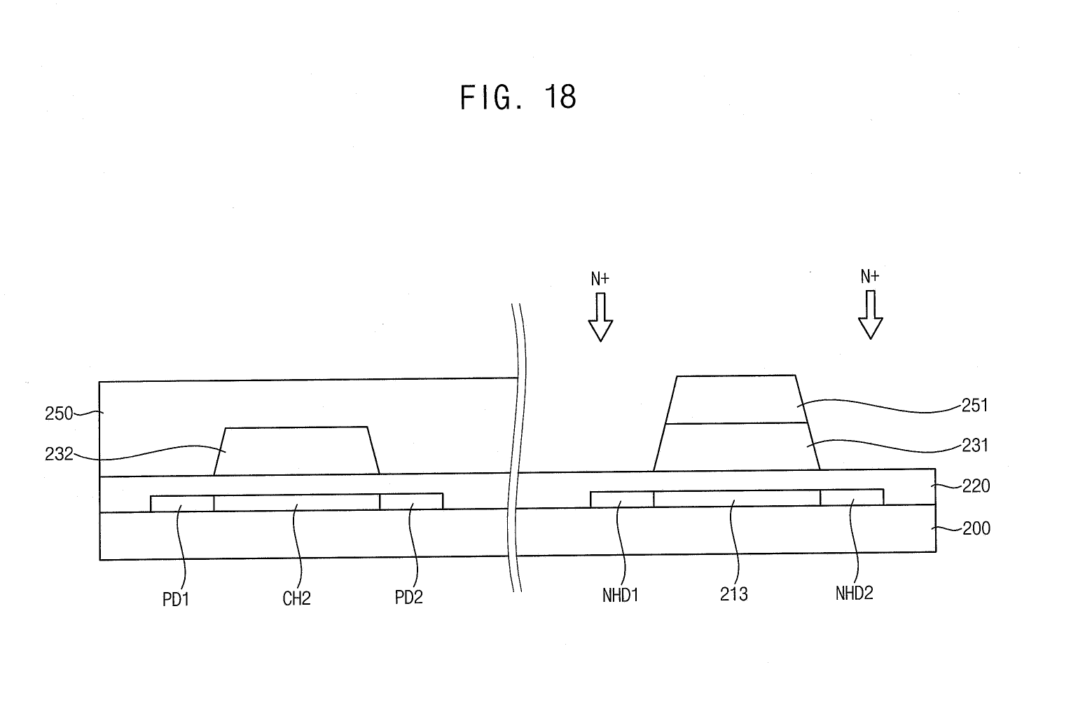

Referring to FIG. 18, the gate metal layer 230 is etched using the second photoresist layer including the second mask pattern 251 as a mask to form a gate pattern 231. For example, the gate metal layer 230 may be etched by a dry-etching process using plasma or the like. As the gate pattern 231 is formed, the first insulation layer 220 may be exposed in an area surrounding or adjacent to the gate pattern 231.

Thereafter, n-type impurities may be provided to the first semiconductor area 212 through an exposed portion of the first insulation layer 220 with a high concentration. Thus, a peripheral portion of the first semiconductor area 212, which does not overlap the gate pattern 231, is doped with n-type impurities with a high concentration to form a first high-concentration-doped area NHD1 and a second high-concentration-doped area NHD2. In the first semiconductor area 212, an overlapping portion 213, which overlaps the gate pattern 231, is protected by the gate pattern 231 to remain without being doped.

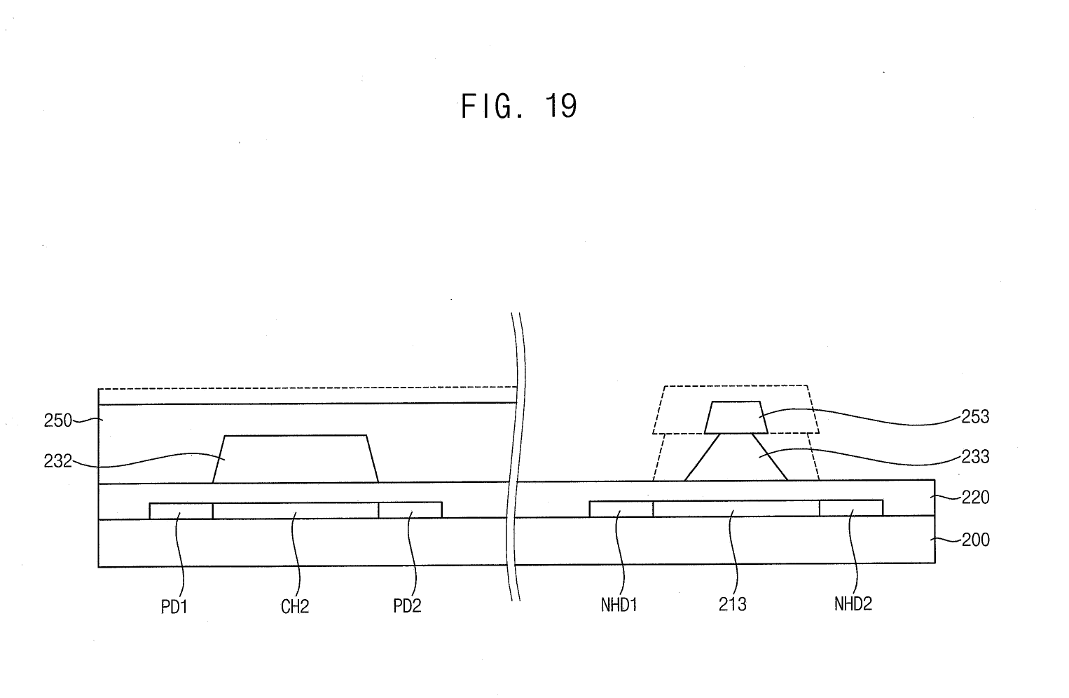

Referring to FIG. 19, the gate pattern 231 and the second mask pattern 251 are etched by an ashing process. As a result of the ashing process, a width of the gate pattern 231 may be reduced to form a first gate electrode 233.

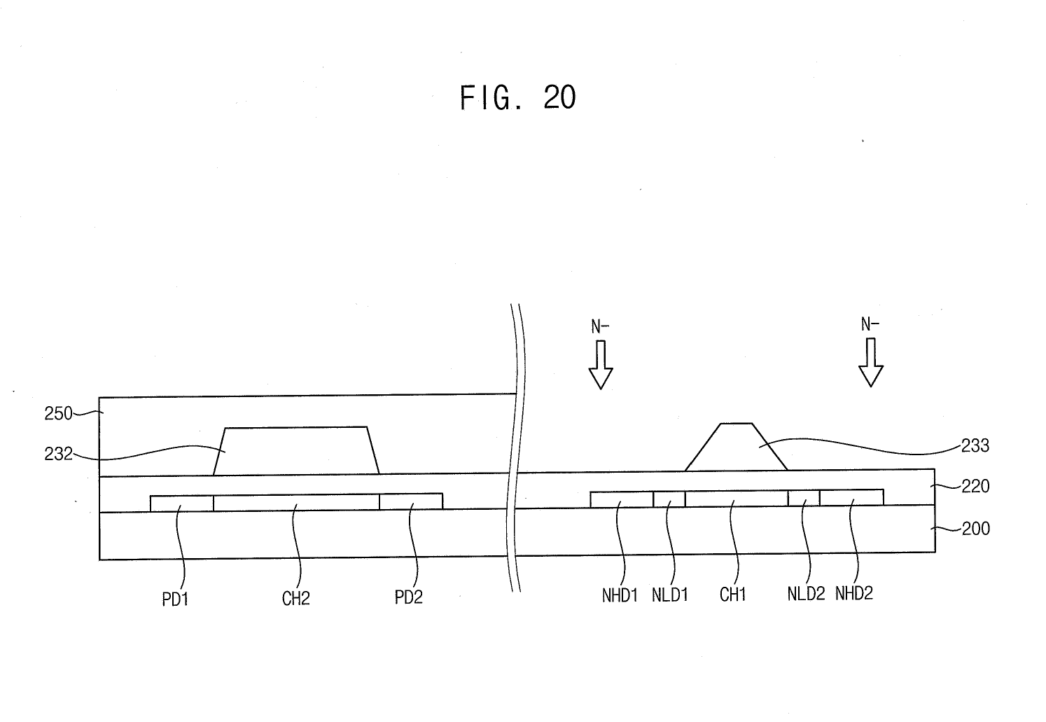

Referring to FIG. 20, a low concentration of n-type impurities may be provided to a remaining semiconductor pattern 213 through an exposed portion of the first insulation layer 220. Thus, a peripheral portion of the remaining semiconductor pattern 213, which does not overlap the first gate electrode 233, is doped with a low concentration of n-type impurities to form a first low-concentration-doped area NLD1 and a second low-concentration-doped area NLD2. In the remaining semiconductor pattern 213, a portion overlapping the first gate electrode 233 is protected by the first gate electrode 233. Thus, the portion remains without being doped to define a first channel area CH1.

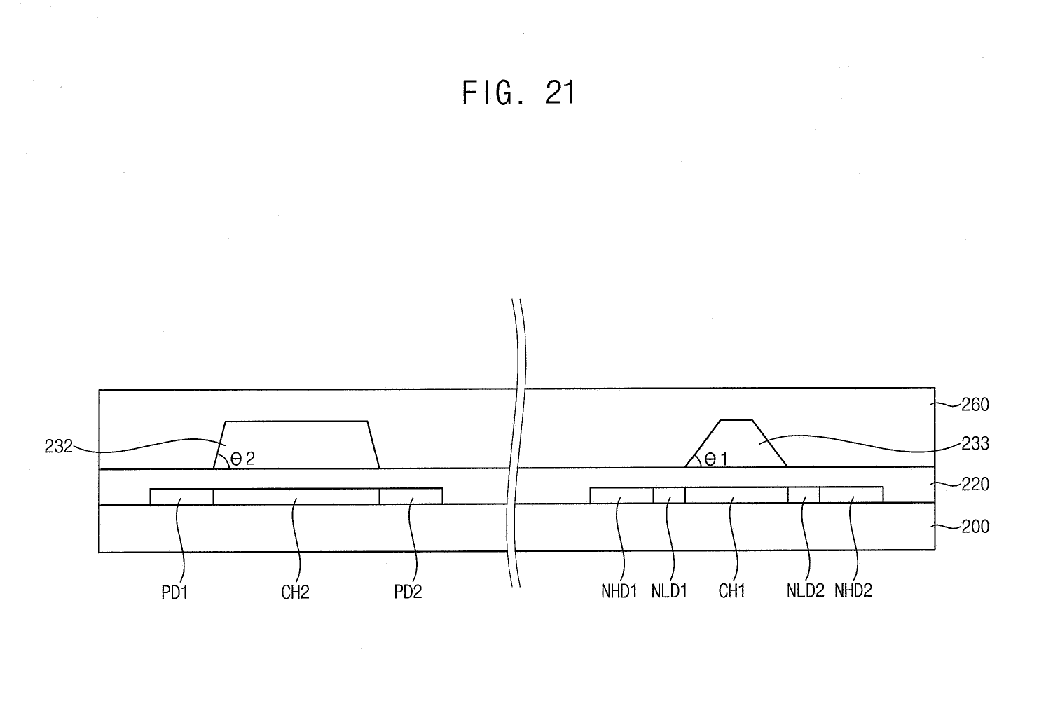

Referring to FIG. 21, the second photoresist layer 250 is removed, and a second insulation layer 260 is formed to cover the first gate electrode 233, the second gate electrode 232, and the first insulation layer 220. The steps that follow may be substantially the same as corresponding steps that were explained above.

A taper angle θ1 of the first gate electrode 233 may be smaller than a taper angle θ2 of the second gate electrode 232.

Exemplary embodiments of the present inventive concept may be used for manufacturing a display device including a circuit illustrated in FIG. 1, however, the present disclosure is not limited thereto, and may be used for manufacturing a display device having various circuit configurations including an NMOS transistor and a PMOS transistor. For example, according to an exemplary embodiment of the present disclosure, the first transistor TR1 and the third transistor TR3 may be NMOS transistors, and the second transistor TR2 may be a PMOS transistor. According to an exemplary embodiment of the present disclosure, a display device may have a 2T1C configuration, in which a driving transistor for providing current to an organic light-emitting diode is an NMOS transistor, and a switching transistor for operating the driving transistor is a PMOS transistor. Furthermore, the present inventive concept is not limited to a pixel circuit of a display part, and may be used for circuits of a gate driving part, a data driving part or the like.

Exemplary embodiments of the present inventive concept may be used for an organic light-emitting display device, however, the present invention is not limited thereto, and may be used for manufacturing integrated circuits for a liquid crystal display device.

Hereinafter, exemplary embodiments of the present disclosure will be explained more fully with reference to various examples and various comparative examples.

It is to be understood, however, that exemplary embodiments of the present invention may be implemented by combining any of the features described below for any of the various examples and various comparative examples.

### Example 1

A circuit element including an NMOS transistor and a PMOS transistor may be prepared according to the method previously explained with reference to FIGS. 2 to 9. In the process of manufacturing the circuit element, a thickness of a molybdenum layer provided for a gate metal layer may be about 2,500 Å, a thickness of a silicon oxide layer provided for an insulation layer between a gate electrode and a channel may be about 1,200 Å, and time for an ashing process for forming a gate skew may be about 80 seconds. In the circuit element, a taper angle of a PMOS gate electrode may be about 85°, a taper angle of a NMOS gate electrode may be about 56°, and a length of a low-concentration-doped area (LDD) may be about 0.74 μm.

### Example 2

A circuit element including an NMOS transistor and a PMOS transistor may be prepared according to the method of Example 1 except for an ashing time that may be changed to be 100 seconds. In the circuit element, a taper angle of a PMOS gate electrode may be about 85°, a taper angle of a NMOS gate electrode may be about 46°, and a length of a low-concentration-doped area (LDD) may be about 1.12 μm.

### Comparative Example 2

A circuit element including an NMOS transistor and a PMOS transistor may be prepared according the method of Example 1 except for omitting an ashing process. In the circuit element, a taper angle of an NMOS gate electrode and a POMS gate electrode may be commonly about 85°, and a length of a low-concentration-doped area (LDD) may be about 0.26 μm.

Off currents (loft) of the circuit elements according to Example 1, Example 2 and Comparative Example 1 may be measured and represented by the following Table 1.

TABLE 1

| | Ioff (Vgs = 0) | | |
|---|---|---|---|
| | Comparative | | |
| | Example 1 | Example 1 | Example 2 |
| Vds | (LDD 0.26 μm) | (LDD 0.74 μm) | (LDD 01.12 μm) |
| 0.1 V | 3.20E−14 | 4E−14 | 5.3E−15 |
| 5.1 V | 3.75E−14 | 4.35E−14 | 3.91E−15 |
| 10 V | 8.95E−14 | 1.42E−13 | 3.56E−15 |
| 15 V | 3.02E−13 | 3.84E−13 | 2.156E−14 |
| 20 V | 3.40E−12 | 2.065E−12 | 8.525E−14 |
| 25 V | 3.26E−11 | 1.6915E−11 | 3.8896E−13 |
| 30 V | 8.15E−11 | 1.09215E−10 | 7.26931E−10 |
| 35 V | breakdown | breakdown | breakdown |

Referring to Table 1, it can be noted that an ashing process for forming a gate skew may reduce a taper angle of an NMOS transistor and may increase a length of a low-concentration-doped area. Furthermore, it can be noted that off-current of a circuit element may be reduced depending on taper angle difference between a gate electrode of a PMOS transistor and a gate electrode of an NMOS transistor.

Exemplary embodiments of the present inventive concept may be used for a display device such as an organic light-emitting display device, a liquid crystal display device or the like.

Exemplary embodiments described herein are illustrative, and many variations can be introduced without departing from the spirit of the disclosure or from the scope of the appended claims. For example, elements and/or features of different exemplary embodiments may be combined with each other and/or substituted for each other within the scope of this disclosure and appended claims.

What is claimed is:

1. A method for manufacturing a display device, the method comprising:
forming a semiconductor pattern including a first semiconductor area and a second semiconductor area on a base substrate;
forming a first insulation layer covering the semiconductor pattern;
forming a gate metal layer on the first insulation layer;
etching the gate metal layer to form a gate pattern at least partially overlapping the first semiconductor area;
doping a first area of the first semiconductor area with a high concentration of n-type impurities to form a high-concentration-doped area;
etching the gate pattern to form a first gate electrode having a taper angle smaller than a taper angle of the gate pattern;
doping a second area of the first semiconductor area, contacting the first area of the first semiconductor area, with a low concentration of n-type impurities to form a low-concentration-doped area;
etching the gate metal layer to form a second gate electrode at least partially overlapping the second semiconductor area and having a taper angel larger than the taper angle of the first gate electrode; and
doping the second semiconductor area with p-type impurities to form a p-doped area.

2. The method of claim 1, wherein the gate metal layer is etched by a dry-etching process, and the gate pattern is etched by an ashing process.

3. The method of claim 2, further comprising forming a first photoresist layer on the gate metal layer, wherein the first photoresist layer partially exposes the gate metal layer and includes a first mask pattern at least partially overlapping the first semiconductor area, and
wherein the gate pattern is formed using the first mask pattern as a mask.

4. The method of claim 3, further comprising forming a second photoresist layer on the gate metal layer, wherein the second photoresist layer partially exposes the gate metal layer, covers the first gate electrode and the first insulation layer adjacent to the first gate electrode, and includes a second mask pattern at least partially overlapping the second semiconductor area, and
wherein the second gate electrode is formed using the second mask pattern as a mask.

5. The method of claim 2, further comprising forming a first photoresist layer on the gate metal layer, wherein the first photoresist layer at least partially exposes the gate metal layer and includes a first mask pattern at least partially overlapping the second semiconductor area, and
wherein the second gate electrode is formed using the first mask pattern as a mask.

6. The method of claim 5, further comprising forming a second photoresist layer on the gate metal layer, wherein the second photoresist layer at least partially exposes the gate metal layer, covers the second gate electrode and the first insulation layer adjacent to the second gate electrode, and includes a second mask pattern at least partially overlapping the first semiconductor area, and
wherein the first gate electrode is formed using the second mask pattern as a mask.

7. The method of claim 2, wherein the taper angle of the first gate electrode is about 30° to about 70°, and the taper angle of the second gate electrode is about 60° to about 90°.

8. The method of claim 2, wherein a difference between the taper angle of the first gate electrode and the taper angle of the second gate electrode is about 20° to about 40°.

9. The method of claim 8, wherein a difference between the taper angle of the first gate electrode and the taper angle of the second gate electrode is about 30° to about 40°.

10. The method of claim 2, wherein the first insulation layer includes a first area at least partially overlapping the first gate electrode, a second area at least partially overlapping the low-concentration-doped area, and a third area at least partially overlapping the high-concentration-doped area, wherein a thickness of the first area is larger than a thickness of the second area, and the thickness of the second area is larger than a thickness of the third area.

11. The method of claim 10, wherein the thickness of the third area is greater than or equal to 80% of the thickness of the first area.
